(19) United States
(12) Patent Application Publication
(10) Pub. No.: US 2012/0234383 A1
(43) Pub. Date: Sep. 20, 2012

(54) CONDUCTIVE METAL PASTE FOR A METAL-WRAP-THROUGH SILICON SOLAR CELL

(75) Inventors: KENNETH WARREN HANG, Cary, NC (US); Yueli Wang, Cary, NC (US)

(73) Assignee: E.I.DU PONT DE NEMOURS AND COMPANY, Wilmington, DE (US)

(21) Appl. No.: 13/402,103

(22) Filed: Feb. 22, 2012

Related U.S. Application Data
(60) Provisional application No. 61/452,767, filed on Mar. 15, 2011.

(51) Int. Cl. H01L 31/0224; H01B 1/02

(52) U.S. Cl. 136/256; 252/513; 252/514; 252/512

(57) ABSTRACT

A conductive metal via paste comprising particulate conductive metal, phosphorus-containing material, glass frit, and an organic vehicle. is particularly useful in providing the metallization of the holes in the silicon wafers of MWT solar cells. The result is a metallic electrically conductive via between the collector lines on the front side and the emitter electrode on the back-side of the solar cell. The paste can also be used to form the collector lines on the front-side of the solar cell and the emitter electrode on the back-side of the solar cell. Also disclosed are metal-wrap-through silicon solar cells comprising the fired conductive metal paste.

### FIELD OF THE INVENTION

This invention is directed to a conductive metal paste for use in a metal-wrap-through (MWT) silicon solar cell and to the respective MWT silicon solar cells made with the conductive metal paste.

### TECHNICAL BACKGROUND OF THE INVENTION

A conventional solar cell with a p-type (p-doped) silicon base has an n-type (n-doped) emitter in the form of an n-type diffusion layer on its front-side. This conventional silicon solar cell structure uses a negative electrode to contact the front-side, i.e. the sun side, of the cell and a positive electrode on the back-side. It is well known that radiation of an appropriate wavelength falling on a p-n junction of a semiconductor serves as a source of external energy to generate electron-hole pairs. The potential difference that exists at a p-n junction causes holes and electrons to move across the junction in opposite directions, thereby giving rise to flow of an electric current that is capable of delivering power to an external circuit. Most solar cells are in the form of a silicon wafer that has been metallized, i.e., provided with metal electrodes which are electrically conductive. Typically, the front-side metallization is in the form of a so-called H pattern, i.e. in the form of a grid cathode comprising thin parallel finger lines (collector lines) and busbars intersecting the finger lines at right angles, whereas the back-side metallization is an aluminum anode in electric connection with silver or silver/aluminum busbars or tabs. The photoelectric current is collected by means of these two electrodes.

Alternatively, a reverse solar cell structure with an n-type silicon base is also known. This cell has a front p-type silicon surface (front p-type emitter) with a positive electrode on the front-side and a negative electrode to contact the back-side of the cell. Solar cells with n-type silicon bases (n-type silicon solar cells) can in theory produce higher efficiency gains compared to solar cells with p-type silicon bases owing to the reduced recombination velocity of electrons in the n-doped silicon.

As in the case of the conventional silicon solar cells, MWT silicon solar cells can be produced as MWT silicon solar cells having a p-type silicon base or, in the alternative, as MWT silicon solar cells having an n-type silicon base. As in conventional solar cells, the emitter of a MWT solar cell is typically covered with a dielectric passivation layer which serves as an antireflective coating (ARC) layer. However, MWT silicon solar cells have a cell design different than that of the conventional solar cells. The front-side electrodes of conventional solar cells reduce the effective photosensitive area available on the front-side of the solar cell and thereby reduce performance of the solar cell. MWT solar cells have both electrodes on the back-side of the solar cell. This is accomplished by drilling, e.g., with a laser, small holes that form vias between the front-side and the back-side of the cell.

The front-side of the MWT silicon solar cell is provided with a front-side metallization in the form of thin conductive metal collector lines which are arranged in a pattern typical for MWT silicon solar cells, e.g., in a grid- or web-like pattern or as thin parallel finger lines. The collector lines are applied from a conductive metal paste having fire-through capability. After drying, the collector lines are fired through the front-side dielectric passivation layer thus making contact with the front surface of the silicon substrate. The term “metal paste having fire-through capability” means a metal paste which etches and penetrates through (fires through) a passivation or ARC layer during firing thus making electrical contact with the surface of the silicon substrate.

The inside of the holes and, if present, the narrow rim around the front-edges of the holes, i.e., the diffusion layer not covered with the dielectric passivation layer, is provided with a metallization either in the form of a conductive metal layer on the sides of the hole or in the form of a conductive metal plug that completely fills the hole with conductive metal. The terminals of the collector lines overlap with the metallizations of the holes and are thus electrically connected therewith. The collector lines are applied from a conductive metal paste having fire-through capability. The metallizations of the holes are typically applied from a conductive metal paste and then fired. The metallizations of the holes serve as emitter contacts and form back-side electrodes connected to the emitter or electrically contact other metal deposits which serve as the back-side electrodes connected to the emitter.

The back-side of a MWT silicon solar cell also has the electrodes directly connected to the silicon base. These electrodes are electrically insulated from the metallizations of the holes and the emitter electrodes. The photoelectric current of the MWT silicon solar cell is collected from these two different back-side electrodes, i.e., those connected to the emitter and those connected to the base.

Firing is typically carried out in a belt furnace for a period of several minutes to tens of minutes with the wafer reaching a peak temperature in the range of 550° C. to 900° C.

The efficiency of the MWT solar cells is improved since the emitter electrode is located on the back-side and thereby reduces shadowing of the photosensitive area available on the front-side of the solar cell. In addition the emitter electrodes can be larger in size and thereby reduce ohmic losses and all electrical connections are made on the back-side.

When producing a MWT solar cell there is a need for a conductive paste that results in a metalized hole that: (1) has sufficiently low series resistance between the collector lines and the emitter electrode, (2) has good adhesion to the sides of the hole and to the silicon on the backside of the solar cell and (3) has sufficiently high shunting resistance to prevent deleterious electrical connection between portions of the cell, i.e., the emitter and the base.

### SUMMARY OF THE INVENTION

The present invention relates to conductive metal paste comprising:
(a) particulate conductive metal selected from the group consisting of silver, copper, nickel and mixtures thereof;
(b) phosphorus-containing material;
(c) glass frit; and
(d) an organic vehicle, wherein the particulate conductive metal, the phosphorus-containing compound and the glass frit are dispersed in the organic vehicle and wherein the phosphorus-containing material reacts at temperatures of 550° C. to 900° C. with the glass frit to form an insulating glass.

This conductive metal paste is particularly useful in providing the metallization of the holes in the silicon wafers of MWT solar cells. This metallization results in a metallic electrically conductive via between the collector lines on the front side and the emitter electrode on the back-side of the solar cell.

Also provided is a metal-wrap-through silicon solar cell comprising the fired conductive metal paste of the invention.

### DETAILED DESCRIPTION OF THE INVENTION

The conductive metal via paste of the present invention allows for the production of MWT silicon solar cells with improved performance. The conductive metal paste has good hole filling capability. The fired conductive metal paste adheres well to the inside of the holes of the silicon wafer and to the silicon on the backside of the solar cell and provides sufficiently high shunting resistance and sufficiently low series resistance.

In one embodiment, the conductive metal paste comprises particulate conductive metal, phosphorus-containing material, glass frit, and an organic vehicle. In another embodiment, the conductive metal paste further comprises a sintering inhibitant.

The conductive metal paste comprises at least one particulate electrically conductive metal selected from the group consisting of silver, copper and nickel. Preferably, the particulate electrically conductive metal is silver. The particulate silver may be comprised of silver or a silver alloy with one or more other metals such as copper, nickel and palladium. The particulate electrically conductive metal may be uncoated or at least partially coated with a surfactant. The surfactant may be selected from, but is not limited to, stearic acid, palmitic acid, lauric acid, oleic acid, capric acid, myristic acid and linolic acid and salts thereof, e.g., ammonium, sodium or potassium salts.

The particle size of the particulate electrically conductive metal is in the range of 0.5 to 5 μm. The term “particle size” is used herein to indicate the median particle diameter, d₅₀, as determined by means of laser diffraction.

The particulate electrically conductive metal is present in the conductive metal paste in a proportion of 70 to 92 wt %, based on the total weight of the conductive metal paste composition. In one embodiment the particulate electrically conductive metal is present in the conductive metal paste in a proportion of 75 to 90 wt %,

The conductive metal paste also comprises phosphorus-containing material and glass frit. The phosphorus-containing material is such that it reacts at temperatures of 550° C. to 900° C. with the glass frit to form an insulating glass. The phosphorus-containing material is selected from the group consisting of phosphorus oxides, phosphorus salts, phosphorus oxyacids, phosphorus sulfides, phosphides, phosphorus-containing surfactants, phosphorus-containing glass frits and mixtures thereof. The phosphorus salts include phosphonium salts, phosphates and phosphinates. The phosphorus oxyacids include phosphoric acid, phosphorous acid and hypophosphorous acid. In various different embodiments the phosphorus-containing material comprises one or more materials selected from the group consisting of H₃PO₄, P₂O₅, BPO₄ and phosphorus-containing organic compounds such as phosphonium-based ionic liquids and, in particular, trihexyl(tetradecyl)phosphonium bis 2,4,4-(trimethylpentyl)phosphinate.

In one embodiment, the amount of phosphorus in the conductive metal paste is from 0.1 to 3 wt % based on the total weight of the conductive metal paste. In another embodiment, the amount of phosphorus in the conductive metal paste is from 0.5 to 2 wt % based on the total weight of the conductive metal paste. In still another embodiment, the amount of phosphorus in the conductive metal paste is from 1 to 2 wt percent based on the total weight of the conductive metal paste.

The glass frits used herein are produced by conventional glass making techniques. Typically, the ingredients are weighted, then mixed in the desired proportions, and heated in a bottom-loading furnace to form a melt in a platinum alloy crucible. Heating is typically conducted to a peak temperature of 1000° C. to 1200° C. and for a time such that the melt becomes entirely liquid and homogeneous. The glass melts are then quenched by pouring on the surface of counter rotating stainless steel rollers to form a 10-20 mil thick platelet of glass or by pouring into a water tank. The resulting glass platelet or water quenched frit is milled to form a powder.

An average particle size of the glass frit used in the present conductive metal paste is in the range of 1 to 5 μm. The softening point of the glass frit (Tc: second transition point of DTA) is in the range of 300° C. to 600° C. The amount of glass frit in the conductive metal paste is from 0.1 to 3 wt % based on the total weight of the conductive metal paste composition. Preferably, the amount of glass frit in the conductive metal paste is from 0.2 to 1 wt %. The glass frits are characterized by the ingredients used to make the glass frit.

In some embodiments, the glass frit used is lead-free with the lead-free glass frit comprising 0.5 to 15 wt % SiO₂, 0.3 to 10 wt % Al₂O₃, 67 to 75 wt % Bi₂O₃, and further comprising 0 to 12 wt % B₂O₃, 0 to 16 wt % ZnO, 0 to 6 wt. % BaO, wherein the wt %'s are based on the total weight of the glass frit. The glass frit may also contain other ingredients such as ZrO₂, P₂O₅, SnO₂ and BiF₃. Specific compositions for lead-free glass frits that can be used in the conductive metal paste are shown in Table I. The table shows the wt % of the various ingredients in glass frits A-N, based on the total weight of the glass frit.

TABLE I

| | SiO2 | Al2O3 | ZrO2 | B2O3 | ZnO | BaO | Bi2O3 | P2O5 | SnO2 | BiF3 |
|---|---|---|---|---|---|---|---|---|---|---|
| A | 3.00 | 3.00 | | 12.00 | 7.00 | 5.00 | 70.00 | | | |
| B | 5.00 | 5.00 | | 8.00 | 7.00 | 5.00 | 70.00 | | | |
| C | 6.00 | 3.00 | | 6.00 | 7.00 | 4.00 | 74.00 | | | |
| D | 2.60 | 0.85 | | 8.10 | 13.20 | 2.25 | 73.00 | | | |
| E | 1.50 | 3.00 | | 7.50 | 14.50 | 3.50 | 70.00 | | | |
| F | 1.00 | 0.50 | | 9.50 | 13.00 | 3.00 | 73.00 | | | |
| G | 1.00 | 0.50 | | 9.50 | 13.00 | 3.00 | 73.00 | | | |
| H | 1.90 | 0.60 | | 8.20 | 13.50 | 2.60 | 73.20 | | | |
| I | 10.49 | 1.94 | 1.14 | | | | 73.94 | 2.70 | | 9.80 |
| J | 11.88 | 6.19 | | 9.72 | | | 72.21 | | | |
| K | 1.00 | 0.50 | | 9.50 | 13.00 | 3.00 | 73.00 | | | |
| L | 7.50 | 2.90 | | 7.50 | 11.00 | 1.90 | 69.20 | | | |
| M | 2.00 | 0.80 | | 8.40 | 13.40 | 2.40 | 72.50 | | 0.50 | |
| N | 7.17 | 7.17 | | 8.50 | 7.16 | | 70.00 | | | |

In other embodiments, the glass frit is lead-containing with the lead-containing glass frit comprising 48 to 58 wt % PbO, 20 to 30 wt % SiO₂ to 16 wt % ZnO, 4 to 7 wt % Al₂O₃ and 7 to 15 wt % B₂O₃ and further comprising 0 to 3 wt % ZnO and 0 to 5 wt % TiO₂. Specific compositions for lead-containing glass frits that can be used in the conductive metal paste are shown in Table II. The table shows the wt % of the various ingredients in glass frits P-S, based on the total weight of the glass frit.

TABLE II

| | SiO2 | Al2O3 | PbO | B2O3 | ZnO | TiO2 |
|---|---|---|---|---|---|---|
| P | 28.00 | 4.70 | 55.90 | 8.10 | | 3.30 |
| Q | 26.06 | 6.69 | 50.96 | 8.94 | 2.79 | 4.56 |
| R | 26.06 | 6.69 | 50.96 | 8.94 | 2.79 | 4.56 |
| S | 22.66 | 6.35 | 56.94 | 14.04 | | |

The conductive metal paste comprises an organic vehicle. The organic vehicle is an organic solvent or an organic solvent mixture or, in another embodiment, the organic vehicle is a solution of organic polymer in organic solvent.

A wide variety of inert viscous materials can be used as an organic vehicle. The organic vehicle is one in which the other constituents, i.e., the particulate conductive metal, the phosphorus-containing material, and the glass frit are dispersible with an adequate degree of stability. The properties, in particular, the rheological properties, of the organic vehicle must be that they lend good application properties to the conductive metal paste composition, including: stable dispersion of insoluble solids, appropriate viscosity and thixotropy for application, appropriate wettability of the paste solids, a good drying rate, and good firing properties.

The organic vehicle is typically a solution of one or more polymers in one or more solvents. The most frequently used polymer for this purpose is ethyl cellulose. Other examples of polymers are ethylhydroxyethyl cellulose, wood rosin, mixtures of ethyl cellulose and phenolic resins, polymethacrylates of lower alcohols, and monobutyl ether of ethylene glycol monoacetate. The most widely used solvents found in thick film compositions are ester alcohols and terpenes such as alpha- or beta-terpineol or mixtures thereof with other solvents such as kerosene, dibutylphthalate, butyl carbitol, butyl carbitol acetate, hexylene glycol and high boiling alcohols and alcohol esters. In addition, volatile liquids for promoting rapid hardening after application on the substrate can be included in the vehicle. Various combinations of these and other solvents are formulated to obtain the viscosity and volatility requirements desired.

The organic vehicle content in the conductive metal paste is dependent on the method of applying the paste and the kind of organic vehicle used. In one embodiment, it is from 5 to 25 wt %, based on the total weight of the conductive metal paste composition. In another embodiment, it is from 7 to 15 wt. %, based on the total weight of the conductive metal paste composition. These wt % include the organic solvent, any organic polymer and any other organic additives.

The conductive metal paste may comprise one or more other organic additives, for example, surfactants, thickeners, rheology modifiers and stabilizers. An organic additive may be part of the organic vehicle. However, it is also possible to add an organic additive separately when preparing the conductive metal paste.

In one embodiment, the conductive metal paste further comprises a sintering inhibitant. The sintering inhibitant slows down sintering and is believed to thereby reduce shunting. The sintering inhibitant is selected from the group consisting of titanium resinate, titanium dioxide, aluminum oxide, zinc oxide, manganese dioxide, silicon dioxide, rhodium resinate and any compound that decomposes into one of the above oxides at temperatures of 550° C. to 900° C. and mixtures thereof.

The application viscosity of the conductive metal paste may be 20 to 200 Pa·s when it is measured at a spindle speed of 10 rpm and 25° C. by a utility cup using a Brookfield HBT viscometer and #14 spindle.

The conductive metal paste is applied to the holes of the silicon wafer to provide metallization and a conducting via from the front-side to the back-side of the metal-wrap-through solar cell, or from the backside to the front side. The conductive metal paste is applied in a way to completely fill the hole with conductive metal or in the form of a layer to cover at least the inside of the holes with a metallization, i.e. to form the metallizations of at least the inside of the holes.

The method of conductive metal paste application may be printing, for example, screen printing. The application may be performed from the front-side and/or from the back-side of the solar cell.

After application, the conductive metal paste is dried, for example, for a period of 1 to 10 minutes with the silicon wafer reaching a peak temperature in the range of 100° C. to 300° C. Drying can be carried out making use of, for example, belt, rotary or stationary driers and in particular, IR (infrared) belt driers.

The dried conductive metal paste is fired to form the finished metallizations of the holes. These metallizations serve as emitter contacts and back-side contacts of the MWT silicon solar cell. The firing is performed for a period of 1 to 5 minutes with the silicon wafer reaching a peak temperature in the range of 550° C. to 900° C. The firing can be carried out making use of single or multi-zone belt furnaces, in particular, multi-zone IR belt furnaces. The firing can take place in an inert gas atmosphere or in the presence of oxygen, e.g., in the presence of air. During firing the organic substance including non-volatile organic material and the organic portion not evaporated during the drying is removed. The organic substance removed during firing includes organic solvent, organic polymer and any organic additives present.

The conductive metal paste firing process can be a cofiring process in which front-side metallization in the form of thin conductive metal collector lines arranged in a pattern typical for MWT silicon solar cells and applied from a conductive metal paste and/or silver backside collector contacts applied from a back-side silver paste are fired at the same time.

Also provided is a metal-wrap-through silicon solar cell comprising the fired conductive metal paste of the invention.

### Example

This Example was carried out to prepare a conductive metal paste of the invention using the following components in the parts by weight indicated:
4.5 parts of organic vehicle of ethyl cellulose dissolved in solvent, wherein the ethyl cellulose is about 10 wt % of the total weight of the solution;
4.0 parts terpineol;
0.5 part of Thixotrol® for paste rheology (obtained from Rheox, Inc., Hightstown, N.J.);
0.2 part of butylated hydroxytolueneionol (obtained from PMC Specialities Group, Cincinnati, Ohio);
5 parts of solution containing 85 wt % phosphoric acid;
0.5 part of glass frit G of Table I;
85.0 parts of Ag powder;
0.2 part octylene glycol titanate, a titanium resinate sintering inhibitor (obtained from Tioxide Specialities Ltd.)

All the components except the glass frit and the Ag powder were mixed in a mixing can for minutes. The glass frit and the silver powder were then added and mixing was continued for another 15 minutes. Since the Ag powder was the major portion of the solids, it was added incrementally to insure better wetting. When mixing was completed, the resulting paste was repeatedly passed through a 3-roll mill with progressively increased pressures from 0 to 400 psi. The gap of the mill was adjusted to 1 mil (25.4 μm). The degree of dispersion was measured by fineness of grind (FOG) to insure that the FOG was less than or equal to 20/10.

### Comparative Experiment

This Comparative Experiment was carried out to prepare a paste containing less than 0.1 wt % phosphorus using the following components in the parts by weight indicated:
8.0 parts of organic vehicle of ethyl cellulose dissolved in solvent, wherein the ethyl cellulose is about 10 wt % of the total weight of the solution;
4.0 parts terpineol;
0.75 part of Thixotrol® for paste rheology (obtained from Rheox, Inc., Hightstown, N.J.);
0.2 part of butylated hydroxytolueneionol (obtained from PMC Specialities Group, Cincinnati, Ohio);
1 part solution containing 1 wt % phosphoric acid;
0.25 part of glass frit G of Table I;
85.25 parts of Ag powder;
0.2 part octylene glycol titanate a titanium resinate sintering inhibitor (obtained from Tioxide Specialities Ltd.)

The paste was prepared as described for the Example.

When the pastes from the Example and the Comparative Experiment were used to fill solar cell vias and then fired, the paste of the Example exhibited higher shunt resistance than that of the Comparative Experiment.

What is claimed is:

1. A conductive metal paste comprising:
(a) particulate conductive metal selected from the group consisting of silver, copper, nickel, palladium and mixtures thereof;
(b) phosphorus-containing material;
(c) glass frit; and
(d) an organic vehicle, wherein said particulate conductive metal, said phosphorus-containing compound and said glass frit are dispersed in said organic vehicle and wherein said phosphorus-containing material reacts at temperatures of 550° C. to 900° C. with said glass frit to form an insulating glass.

2. The conductive metal paste of claim 1, further comprising:
(e) a sintering inhibitant selected from the group consisting of titanium resinate, titanium dioxide, aluminum oxide, zinc oxide, manganese dioxide, silicon dioxide, rhodium resinate and any compound that decomposes into one of said oxides at temperatures of 550° C. to 900° C. and mixtures thereof.

3. The conductive metal paste of claim 1, said phosphorus-containing material comprising one or more components selected from the group consisting of phosphorus oxides, phosphorus salts, phosphorus oxyacids, phosphorus sulfides, phosphides, phosphorus-containing surfactants phosphorus-containing glass frits and mixtures thereof.

4. The conductive metal paste of claim 3, said phosphorus-containing material comprising one or more components selected from the group consisting of phosphonium salts, phosphates, phosphinates and mixtures thereof.

5. The conductive metal paste of claim 3, said phosphorus-containing material comprising phosphoric acid.

6. The conductive metal paste of claim 4, said phosphorus-containing material comprising trihexyl(tetradecyl)phosphonium bis 2,4,4-(trimethylpentyl)phosphinate.

7. The conductive metal paste of claim 1, wherein the amount of phosphorus in said conductive metal paste is from 0.1 to 3 wt % based on the total weight of the conductive metal paste.

8. The conductive metal paste of claim 1, wherein said particulate conductive metal is silver.

9. The conductive metal paste of claim 1, wherein the amount of particulate conductive metal in said conductive metal paste is from 70 to 92 wt % based on the total weight of the conductive metal paste composition.

10. The conductive metal paste of claim 2, wherein said sintering inhibitant is titanium resinate.

11. The conductive metal paste of claim 1, wherein said glass frit is lead-free glass frit comprising 0.5 to 15 wt. % SiO₂, 0.3 to 10 wt. % Al₂O₃ and 67 to 75 wt % Bi₂O₃.

12. The conductive metal paste of claim 1, wherein said glass frit is lead-containing glass frit comprising 48 to 58 wt % PbO, 20 to 30 wt % SiO₂, 4 to 7 wt % Al₂O₃ and 7 to 15 wt % B₂O₃.

13. The conductive metal paste of claim 1, wherein the amount of said glass frit in said conductive metal paste is from 0.1 to 3 wt % based on the total weight of the conductive metal paste.

14. A metal-wrap-through silicon solar cell comprising the fired conductive metal paste of any of claims 1-13.
